(19) United States
(12) Patent Application Publication
(10) Pub. No.: US 2006/0252235 A1
(43) Pub. Date: Nov. 9, 2006

(54) Fabrication method for crystalline semiconductor films on foreign substrates

(76) Inventors: Armin Gerhard Aberle, Botany (AU); Per Ingemar Widenborg, Kogarah (AU); Axel Straub, Kingsford (AU); Dirk-Holger Neuhaus, Freiberg/Saxony (DE); Oliver Hartley, Leipzig (DE); Nils-Peter Harder, Hameln (DE)

Correspondence Address: FITCH EVEN TABIN AND FLANNERY, 120 SOUTH LA SALLE STREET, SUITE 1600, CHICAGO, IL, 60603-3406, US

(21) Appl. No.: 10/530,848

(22) PCT Filed: Oct. 7, 2003
(86) PCT No.: PCT/AU03/01313

§ 371 Date: May 6, 2006

(30) Foreign Application Priority Data
Oct. 8, 2002 (AU) 2002951838

(51) Int. Cl. H01L 21/20; H01L 21/36

(52) U.S. Cl. 438/478

(57) ABSTRACT

The invention provides a method of forming a polycrystalline semiconductor film on a supporting substrate of foreign material. The method involves depositing a metal film onto the substrate, forming a film of metal oxide and/or hydroxide on a substrate of the metal, and forming a layer of an amorphous semiconductor material over a surface of the metal oxide and/or hydroxide film. The entire sample is then heated to a temperature at which the semiconductor layer is absorbed into the metal layer and deposited as a polycrystalline layer onto the target surface by metal-induced crystallization. The metal is left as an overlayer covering the deposited polycrystalline layer, with semiconductor inclusions in the metal layer. The polycrystalline semiconductor film and the overlayer are generated by porous interfacial metal oxide nd/or hydroxide film. The metal in the overlayer and the interfacial metal oxide and/or hydroxide film are then removed with an etch which underetches the semiconductor inclusions to form freestanding islands. Finally, the freestanding semiconductor “islands” are removed from the surface of the polycrystalline semiconductor layer by a lift-off process.

### INTRODUCTION

The present invention relates generally to the formation of thin semiconductor films for electronic device fabrication, and in particular the invention provides a method for the formation of thin polycrystalline semiconductor films on foreign substrates, using a thermal budget in each process step that is compatible with the respective foreign substrate. Throughout this text, the term polycrystalline material means material that has an average crystal grain size of above 500 nm and the term thermal budget relates to the amount of heat applied during a process step (i.e., the area below the temperature-time curve of the process step).

### BACKGROUND OF THE INVENTION

Thin films of polycrystalline silicon (pc-Si) on glass or other foreign substrates are very attractive for a wide range of large-area electronic applications, including thin-film photovoltaic (PV) modules, active matrix liquid crystal displays (AMLCDs), and active matrix organic light emitting diode displays (AMOLEDs). Compared to amorphous Si (a-Si) films, their main benefits are higher carrier mobility in display applications and stable energy conversion efficiency and longer product lifetime in PV applications. Generally, one aims to realize c-Si grains with a grain size as large as possible. The use of glass substrates is attractive since they are cheap and transparent. However the limited thermal stability of commercially available low-cost glass substrates severely limits the allowable thermal budget of each fabrication step (as a rule of thumb, the glass temperature must not exceed 650° C. if the process lasts 1 hour or more), resulting in the need for a new technology enabling good material quality at these low temperatures.

As the high melting point of semiconductors is a major obstacle for the formation of polycrystalline semiconductor films at low temperature on foreign substrates, past experimental work dealt primarily with the fabrication of nanocrystalline (or, equivalently, microcrystalline) material. Such fine-grained (<500 nm) material is inevitably of rather low electronic quality. An overview of nanocrystalline silicon materials is given by Schropp and Zeman (Schropp and Zeman, “Amorphous and microcrystalline silicon solar cells”, Kluwer Academic Publishers, Dordrecht (1998)). One approach for the fabrication of nanocrystalline materials is hydrogen-diluted plasma-enhanced chemical vapour deposition (PECVD) at a temperature in the range 200-600° C., whereby the hydrogen is beneficial for both the semiconductor growth process and the passivation of dangling crystallographic bonds within grains and at grain boundaries. A drawback of the hydrogen-diluted PECVD approach with regard to the manufacture of devices that require a rather thick semiconductor film (such as crystalline silicon solar cells) is the low deposition rate for nanocrystalline semiconductor material (much less than 1 nm/s in the case of Si).

Compared to nanocrystalline material, polycrystalline material theoretically has a much better electronic quality, however achieving good-quality polycrystalline material at low temperature on a foreign substrate has proven difficult to achieve. Methods for the low-temperature fabrication of polycrystalline semiconductor films on foreign substrates include solid-phase crystallisation of amorphous semiconductor material (Matsuyama et al., “High-quality polycrystalline silicon thin film prepared by a solid phase crystallization method”, Journal of Non-Crystalline Solids 198-200, pp. 940-944 (1996).), solution growth (Shi et al., “Solution growth of polycrystalline silicon on glass at low temperatures”, Proceedings First World Conference on Photovoltaic Energy Conversion, Hawaii, pp. 1579-1582 (December 1994) (IEEE, New York, 1995).), laser-induced crystallisation of amorphous semiconductor material (Im and Sposili, “Sequential lateral solidification of thin silicon films on SiO₂”, Applied Physics Letters 69, pp. 2864-2866 (1996).), and metal-induced (or, equivalently, metal-mediated) crystallisation of amorphous semiconductor material (Nast et al., “Aluminum-induced crystallization of amorphous silicon on glass substrates above and below the eutectic temperature”, Applied Physics Letters 73, pp. 3214-3216 November 1998, Widenborg and Aberle, “Surface morphology of poly-Si films made by aluminium-induced crystallisation on glass substrates”, Journal of Crystal Growth 242, pp. 270-282 (July 2002), and Jin et. al. “Nickel induced crystallisation of amorphous silicon thin films”, Journal of Applied Physics 84, pp. 194-200 (July 1998).

All of the methods mentioned above have been limited by one or more of the following factors:
i. long processing times,
ii. rough surfaces,
iii. highly doped films
iv. small grain sizes.

Despite a high level of research interest, none of them has as yet led to a commercially available photovoltaic device. The organisation that has come closest to a commercial low-cost thin-film polycrystalline silicon (pc-Si) photovoltaic product is Pacific Solar Pty Ltd of Sydney Australia, producing modules at pilot line scale with an efficiency of about 8%.

For optimum results on foreign substrates, the preparation of polycrystalline material often involves a preliminary step that creates a thin polycrystalline “seed layer” on the substrate, whereby the electronic quality of this seed layer is not critical. Such seed layers can, in principle, be prepared by each of the methods mentioned above.

The metal-induced crystallisation (MIC) process of amorphous semiconductor material as developed at the University of New South Wales (UNSW) (Nast and Hartmann, “Influence of interface and Al structure on layer exchange during aluminum-induced crystallization of amorphous silicon”, Journal of Applied Physics 88, pp. 716-724 (July 2000)) is simple and fast and hence has significant industrial appeal. The metal and semiconductor must be chosen such that they can form a eutectic system, enabling crystallisation at low temperature without the formation of metal silicide. However, with respect to using the resulting polycrystalline semiconductor film for the fabrication of electronic devices or as seed layer, a significant problem of the MIC-prepared polycrystalline semiconductor film is the fact that it is covered by an overlayer consisting of metal and semiconductor inclusions, and that between the polycrystalline semiconductor film and the overlayer there exists an interfacial metal oxide and/or metal hydroxide film with which the semiconductor inclusions are in contact and securely connected (Widenborg and Aberle, “Surface morphology of poly-Si films made by aluminium-induced crystallisation on glass substrates”, Journal of Crystal Growth 242, pp. 270-282 (July 2002)).

The polycrystalline semiconductor film is of primary interest for device fabrication (such as thin-film transistors) or seed layer applications, and hence the metal+semiconductor overlayer and the metal oxide and/or hydroxide interfacial film must be removed by a suitable processing sequence without significantly thinning or damaging the underlying polycrystalline semiconductor film. A conceivable way to achieve this consists in using a method that simultaneously and uniformly removes the metal+semiconductor overlayer. This has proven to be a very difficult task because, in general, the etching rates for the different components of a composite material, such as the overlayer, are not identical. A possible candidate for this purpose is plasma ion etching. For the Si—Al system, the use of an argon plasma has been tested, however, this has proven unsuccessful due to non-uniform etching. Another possible candidate is reactive ion etching with a chlorine plasma. This process, however, appears unattractive due to its technical complexities, as discussed by Wolf and Tauber (Wolf and Tauber, “Silicon processing for the VLSI era”, Vol. 1, Lattice Press, CA, USA (1986). Pages 559 to 564).

Given the difficulties with the above methods for uniform removal of the metal+semiconductor overlayer, selective (or non-simultaneous removal) approaches have been investigated. Teams at UNSW and elsewhere have investigated a wet-chemical method for removal of the metal (see Nast et al, (above) and Niira et al., “Thin film poly-Si formation for solar cells by flux method and Cat-CVD method”, Solar Energy Materials and Solar Cells 69, pp. 107-114 (September 2001).). However, because this method does not remove the semiconductor inclusions, this process creates a very rough polycrystalline semiconductor surface that leads to numerous (and virtually insurmountable) problems during subsequent device processing. The creation of this rough surface will very likely have detrimental effects on the electrical performance of the devices or, in the case of seed layer applications, on the structural properties of a subsequently grown polycrystalline semiconductor film.

Solid phase epitaxy (SPE) of semiconductors on native substrates is a known deposition method in the literature (see for example A. V. Zotov and V. V. Korobtsov, Journal of Crystal Growth 98 p. 519 (1989).). An amorphous semiconductor (for example silicon) is deposited in ultra-high vacuum onto a cool substrate, which consists of the same semiconductor, and then annealed at a temperature high enough to achieve epitaxial crystallisation. The key feature in SPE is a crystallographic transferral of information from the crystalline substrate into the growing epitaxial film and therefore this method is usually associated with a native high-quality crystalline substrate such as a silicon wafer and not with a foreign substrate such as glass.

If the crystalline semiconductor substrate and the epitaxial film consist of the same semiconductor material, the growth method is known in the literature as homo-epitaxy. For two different types of crystalline semiconductor materials which have a close lattice match, a solid phase epitaxial growth is still possible. Such an epitaxial growth by one type of crystalline semiconductor grown on a different crystalline semiconductor substrate is known in the literature as hetero-epitaxy.

Any discussion of documents, acts, materials, devices, articles or the like which has been included in the present specification is solely for the purpose of providing a context for the present invention. It is not to be taken as an admission that any or all of these matters form part of the prior art base or were common general knowledge in the field relevant to the present invention as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY OF THE INVENTION

According to a first aspect, the present invention consists in a method of preparing a polycrystalline semiconductor film on a supporting foreign substrate, the method comprising:
i. Depositing a metal film onto a target surface of the substrate on which the polycrystalline semiconductor film is to be formed;
ii. Forming a film of metal oxide and/or metal hydroxide on a surface of the metal;
iii. Forming a layer of an amorphous semiconductor material over a surface of the metal oxide and/or metal hydroxide;
iv. Heating the entire sample at a temperature at which the semiconductor layer is absorbed into the metal layer and deposited onto the target surface by metal-induced crystallisation (SIC) as a polycrystalline layer (“MIC polycrystalline layer”), whereby the metal is left as an overlayer covering the deposited polycrystalline layer, with semiconductor inclusions in the metal layer, and the polycrystalline semiconductor film and the overlayer separated by a porous interfacial metal oxide and/or metal hydroxide film with which the semiconductor inclusions are in contact;
v. Removal of the metal in the overlayer and the interfacial metal oxide and/or metal hydroxide film with an etch which under-etches the semiconductor inclusions to form freestanding semiconductor islands weakly connected to the polycrystalline layer, without significantly thinning the Underlying polycrystalline semiconductor layer.
vi. Removal of the free-standing semiconductor islands from the surface of the polycrystalline semiconductor layer by a lift-off process.

As the polycrystalline semiconductor will always be highly doped due to metal incorporation, with a doping polarity corresponding to the metal used, a change of the doping polarity of the polycrystalline semiconductor can be induced by suitable process steps. Examples include heating of the polycrystalline semiconductor in the vicinity of a doping source or adding suitable doping impurities in the amorphous semiconductor.

Preferably the substrate provides a planar base on which the semiconductor material is supported. Preferably also a surface on which the semiconductor material is supported is textured to assist light trapping in the semiconductor material.

In some embodiments of the invention the substrate comprises a sheet of a substrate material on which a preliminary layer, such as a thin antireflection layer, is formed, and the target surface is a surface of the preliminary layer, however the target surface may also be a surface of the substrate material on which the process of the present invention is performed directly.

In various embodiments of the invention the substrate is a material selected from the group comprising sapphire, quartz, glass (float, borosilicate and other types), metal, graphite, ceramics, plastics and polymers.

Embodiments of the invention may make use of a semiconductor material selected from the group comprising silicon, germanium, and an alloy of silicon and germanium.

The metal used in various embodiments is selected such that the metal forms a eutectic solution with the selected semiconductor. For example the metal may be selected from the group of metals comprising Be, Al, Zn, Ga, Ag, Cd, In, Sn, Sb and Au. In the preferred embodiment, the semiconductor material is silicon, the metal is aluminium, and the substrate material is glass.

The formation of the metal oxide and/or metal hydroxide film can result in a film of relatively pure metal oxide, a film of relatively pure metal hydroxide, or a mixture of the two. To form an oxide film the metal layer is oxidised in a dry oxygen containing atmosphere (i.e. 0% relative humidity) at room temperature (i.e. 22°±1°) for an appropriate period which may vary according to the metal and the concentration of oxygen in the atmosphere. To form a hydroxide film the metal layer is hydro-oxidised in an oxygen containing atmosphere containing 100% relative humidity at room temperature (i.e. 22°±1°) for an appropriate period which again may vary according to the metal and the concentration of oxygen in the atmosphere. It is also possible to form a hydroxide film by immersing the aluminium surface into water at room temperature (i.e. 22°±1°) or at an elevated temperature. To achieve a mixture of metal oxide and metal hydroxide the process is performed in a semi-dry oxygen containing atmosphere (0%<relative humidity<100%). For less reactive metals this step may be performed at higher temperatures to speed up the process. The metal oxide and/or metal hydroxide film is preferably formed to a thickness in the range of 2 to 30 nm, however thicker films will also allow the process to work albeit possibly at the cost of longer processing times. The result of a longer exposure time is potentially a thicker interfacial film which may slow subsequent processing, however as the interfacial film growth is substantially self limiting this is not likely to be a problem. The result of a shorter exposure time will be a thinner and less uniform interfacial film, resulting in a faster and less controllable MIC process and potentially a failure of the etch to fully underetch the islands.

In the preferred embodiment a thin aluminium hydroxide film is grown by hydro-oxidising the surface of the aluminium layer in an air atmosphere containing 100% relative humidity. To form an aluminium hydroxide film of sufficient thickness, the aluminium surface is exposed to air for at least 1 hour at room temperature (i.e. 22°±1°) and a pressure of 1 atmosphere. However, the oxidation process slows down as the film grows and is essentially self limiting, so that there is no upper limit to the useful time of exposure. Experiments in which an aluminium surface was exposed for two months resulted in a useful MIC polycrystalline layer, however practically speaking a period of 24 hours is usually employed. Increasing the temperature while the hydroxide film is growing will decrease the minimum time required.

If instead of an aluminium hydroxide film an aluminium oxide film is grown, the surface of the aluminium layer is exposed to a dry air atmosphere (0% relative humidity) for at least 6 hours at room temperature (i.e. 22°±1°) and a pressure of 1 atmosphere. As with hydroxide films, the process slows down as the film grows and is essentially self limiting so that there is no upper limit to the useful time of exposure. A period of 24 hours is usually employed. Again increasing the temperature while the oxide film is growing will decrease the minimum time required.

If forming a film which is a mixture of aluminium hydroxide and aluminium oxide, the surface of the aluminium layer is exposed to a semi-dry air atmosphere (0%<relative humidity<100%) for at least 1 hour at room temperature (i.e. 22°±1°) and a pressure of 1 atmosphere. As with oxide and hydroxide films, the process slows down as the film grows and is again essentially self limiting with no upper limit to the useful time of exposure. A period of 24 hours is usually employed. Similarly, increasing the temperature while the oxide/hydroxide film is growing will decrease the minimum time required.

The term aluminium oxide, as used herein, should be understood to include any compound or complex containing aluminium and oxygen for example α-Al₂O₃ or γ-Al₂O₃. Similarly, the term aluminium hydroxide, as used herein, should be understood to include any compound or complex between aluminium, oxygen and hydrogen, for example: boehmite, pseudoboehmite, bayerite, or gibbsite.

For the Al—Si system, the Al and Al oxide and/or hydroxide etch is preferably performed with a phosphoric acid solution, using a 100% solution of 85% phosphoric acid, at about 130° C.±3° for about 20 minutes±30 secs. Weaker solutions of phosphoric acid may also be used with a corresponding increase in etching time. Alternatively the etch may be performed with other acids such as hydrochloric acid.

Embodiments of the invention may make use of a lift-off process selected from the group comprising an acoustic treatment in de-ionized water or other solutions, a brush scrubbing process, or a hydrodynamic jet process.

Preferably the method will include a further processing step wherein, upon completion of the lift-off or doping step, a uniform surface treatment is performed to improve the surface finish of the sample prior to subsequent use of the semiconductor film for device fabrication or as a seed layer. The uniform surface treatment may be selected from the group comprising a KOH etch, a NaOH etch, a HF/HNO₃ etch, a H₃PO₄ etch, an argon plasma etch, or a combination of these.

The metal layer will be in the range of 30-500 nm thick and preferably 200 nm 10% thick. The amorphous semiconductor layer used in the metal-induced crystallisation process is preferably greater in thickness than the metal layer and will preferably be in the range of 30-750 nm thick. When a 200 nm±10% metal layer is used the amorphous semiconductor layer will be preferably 300 nm±10% thick.

The metal-induced crystallisation step is preferably performed by annealing the sample at a temperature at or below 650° C. and preferably at or below 500° C. for 2 hours.

According to a second aspect, the present invention consists in a method of forming a film of polycrystalline semiconductor material on a supporting substrate of foreign material, the method comprising:
i. Forming a polycrystalline seed layer of a seed layer semiconductor material onto a target surface of the substrate on which the polycrystalline semiconductor film is to be formed;
ii. Cleaning the surface of the seed layer to remove any oxides or other contaminants;
iii. Forming, over the cleaned surface of the seed layer, an amorphous layer of the semiconductor material to become the polycrystalline film;
iv. Heating the substrate with the amorphous layer to crystallise the amorphous semiconductor material by solid phase epitaxy (SPE) to form the polycrystalline film (“SPE polycrystalline layer”).

In preferred embodiments the polycrystalline film formed according to the first aspect is used as the seed layer of the second aspect of the invention.

The amorphous layer may be undoped when formed but preferably dopant atoms may be added to the amorphous material as it is formed. Alternatively the semiconductor layer may be doped after it is formed as an amorphous layer or after it is crystallised.

In case of closely lattice matched crystalline semiconductor materials, the amorphous layer deposited on the clean surface of the crystalline seed layer and the seed layer itself can be different semiconductor materials (‘hetero-epitaxial’ solid phase epitaxy). One example of such a hetero-epitaxial process is solid phase epitaxy of germanium on a crystalline silicon seed layer. In this context, the crystalline semiconductor material can consist of an alloy between two or more semiconductor materials. The composition of the alloy can vary throughout the semiconductor film.

In preferred embodiments the amorphous semiconductor film is formed using a high-vacuum or ultra-high-vacuum electron-beam evaporation deposition process at a substrate temperature in the range of 20-650° C. and particularly preferred at a substrate temperature of 150° C. and a pressure in the range of (0.2−1)×10⁻⁷ Torr.

In the SPE crystallisation step, the substrate and amorphous layer are preferably heated to a temperature in the range of 200-650° C. for a period of up to 7 days to crystallise the amorphous semiconductor material, and in a particularly preferred form of the invention the substrate and amorphous layer are heated to a temperature of 540±5° C for a period of 17±0.1 hours to crystallise the amorphous semiconductor material.

The amorphous semiconductor material layer may be doped n- and/or p-type during the semiconductor deposition process (i.e., in-situ). In the case of electron beam evaporation of the semiconductor material, this can be realised using resistively heated dopant effusion cells for n- and p-type dopants located in the vacuum electron-beam evaporation chamber.

The semiconductor material formed over the cleaned seed layer is preferably a material selected from the group comprising silicon, germanium, and an alloy of silicon and germanium.

Preferably also the step of cleaning the seed layer surface comprises the further steps of:
i. immersing the surface for 10 minutes in a fresh 1:1 mixture of hydrogen peroxide and sulfuric acid;
ii. rinsing the surface in de-ionized water;
iii. immersing the surface for 30 seconds in diluted (5%) hydrofluoric acid;
iv. immersing the surface in de-ionized water; and
v. drying the surface with gaseous nitrogen.

This process attaches hydrogen atoms to dangling bonds at the semiconductor surface, preventing oxidation of the surface for up to 60 minutes. Preferably the substrate is transferred to the semiconductor deposition chamber within 60 minutes of completion of the cleaning step to enable deposition onto an unoxidized surface and more preferably within 5 minutes.

The substrate is preferably a material selected from the group comprising quartz, glass (including float glass, borosilicate glass and other glass types), metal, graphite, ceramics, plastics and polymers.

In preferred embodiments the SPE polycrystalline layer is used to form a solar cell and the thickness of the layer is in the range of 0.5 to 3 μm. Preferably also electron beam evaporation is used as semiconductor deposition process and the amorphous material for this layer is deposited at a rate of up to 2 μm/min. Preferably also the deposition rate should be greater than 100 nm/min to minimise the impurity density (mainly oxygen, nitrogen and carbon) in the growing film caused by the vacuum chamber and its components. In the most preferred embodiment of the invention a deposition rate of about 250±20 nm/min is used.

### BRIEF DESCRIPTION OF THE DRAWINGS

Embodiments of the invention will now be described, by way of example, with reference to the accompanying drawings in which:

FIG. 1 illustrates a first step in fabrication of a thin-film polycrystalline layer where a silicon nitride (SiN) layer is deposited onto a clean, planar glass substrate;

FIG. 2 illustrates the sample of FIG. 1 after a thin (200 nm) aluminium layer is deposited (for example by evaporation) onto the SiN layer;

FIG. 3 illustrates the sample of FIG. 2 after the aluminium layer has been oxidized at room temperature, producing a thin aluminium oxide and/or hydroxide layer over the aluminium layer;

FIG. 4 illustrates the sample of FIG. 3 after a thin film (300 nm) of amorphous silicon (a-Si) has been deposited;

FIG. 5 illustrates the sample of FIG. 4 after the amorphous silicon has been crystallized by aluminium-induced crystallisation (AIC) at temperatures below 500° C. for 2 hours in a nitrogen-purged atmospheric-pressure furnace, leaving a metal layer over the crystallised silicon and separated from it by a thin metal oxide and/or hydroxide layer, with crystalline silicon inclusions in the overlayer;

FIG. 6 illustrates the sample of FIG. 5 after the metal in the overlayer and the metal oxide and/or hydroxide film has been removed, leaving free-standing crystalline silicon islands on the AIC polycrystalline layer;

FIG. 7 illustrates the sample of FIG. 6 after the silicon islands have been removed by the lift-off step and a AIC polycrystalline silicon film with a wafer-like smooth surface has been obtained.

FIG. 8 shows a microscopical image (using a focussed ion beam (FIB) microscope) of the top surface of the sample of FIG. 7, demonstrating large crystal grain size.

FIG. 9 graphically illustrates a comparison between the measured reflectance of a high-quality commercial singlecrystalline silicon wafer and the AIC polycrystalline silicon film formed with an AIC process according to the present invention on planar glass;

FIG. 10 illustrates the sample of FIG. 7 after an amorphous n-type (800 nm thick) and ˜5×10¹⁶ cm⁻³ phosphorus doped silicon layer and an amorphous n⁺-type (100 nm and ˜2×10¹⁹ cm⁻³ phosphorus doped) silicon layer have been deposited on the AIC polycrystalline silicon seed layer;

FIG. 11 illustrates the sample of FIG. 10 after a solid phase epitaxy (SPE) process has been performed to crystallise the amorphous silicon layers.

FIG. 12 schematically illustrates a vacuum evaporation chamber in which the amorphous layers seen in FIG. 10 are deposited by electron-beam evaporation and in-situ doped using resistively heated effusion cells for n- and p-type dopants;

FIG. 13 shows a FIB microscopical image of the surface of the sample of FIG. 11, demonstrating large crystal grain size; and

FIG. 14 graphically illustrates a comparison of the reflectances of a high-quality commercial singlecrystalline silicon wafer, the AIC polycrystalline silicon seed layer and the SPE polycrystalline silicon film shown in the microscopical image of FIG. 13.

### DETAILED DESCRIPTION OF AN EMBODIMENT OF THE INVENTION

An embodiment of the invention will now be described which has demonstrated an ability to produce large-grained, island-free polycrystalline silicon with arbitrary doping on planar glass substrates. However, while the process is described for a silicon film on a glass substrate it will be appreciated that the process is also applicable to other semiconductors and foreign substrates.

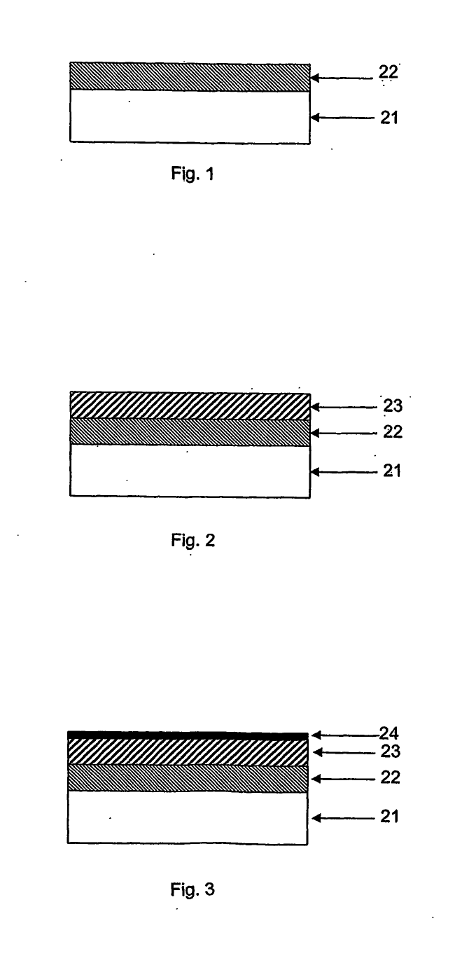

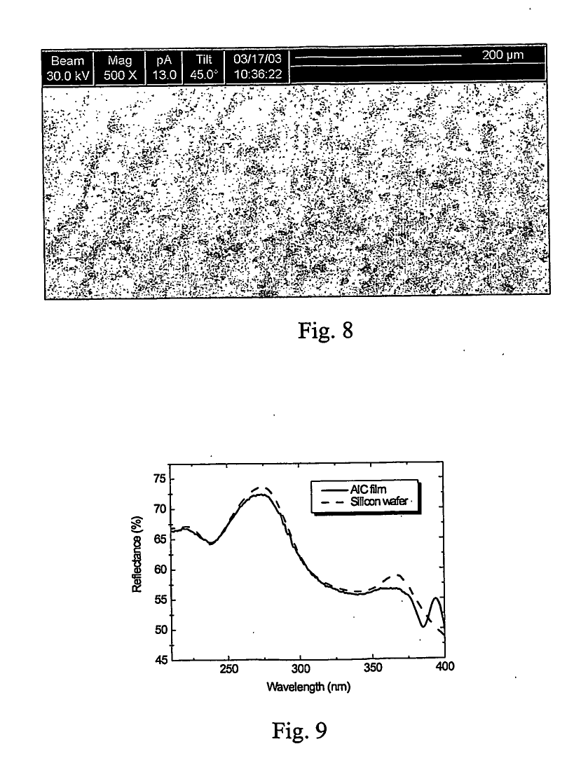

The formation of a device-quality polycrystalline silicon layer on glass is a two-step process, the first of which is to form a high-quality seed layer and the second is to form the device-grade layer over the seed layer. The formation of the seed layer involves the low-temperature (≦650° C.) formation of a polycrystalline semiconductor film on a supporting substrate by means of metal-induced crystallisation (MIC) of amorphous films of the same semiconductor material and is schematically shown in FIGS. 1 and 6. The metal and semiconductor must be chosen such that they can form an eutectic system, and for the purpose of this example silicon and aluminium are used, however it will be recognised that other semiconductor/metal combinations can be selected from the groups of semiconductors and metals given above.

Referring to FIG. 1, the first step of the process is the deposition (for example by PECVD or reactive sputtering or reactive evaporation) of a silicon nitride (SiN) layer 22 onto a clean glass substrate 21. The SiN layer acts as a barrier layer for impurities from the glass and, if the thickness is suitably chosen, as an antireflection coating (AR coating). Next, as seen in FIG. 2, an approximately 200 nm thick aluminium layer 23 is deposited (for example by vacuum evaporation) onto the SiN layer 22. An aluminium hydroxide film 24 is then grown by exposing the aluminium layer 23 to an air atmosphere containing 100% relative humidity at room temperature (i.e. 22°±1°) for 24 hours at 1 atmosphere pressure, to produce the result as seen in FIG. 3.

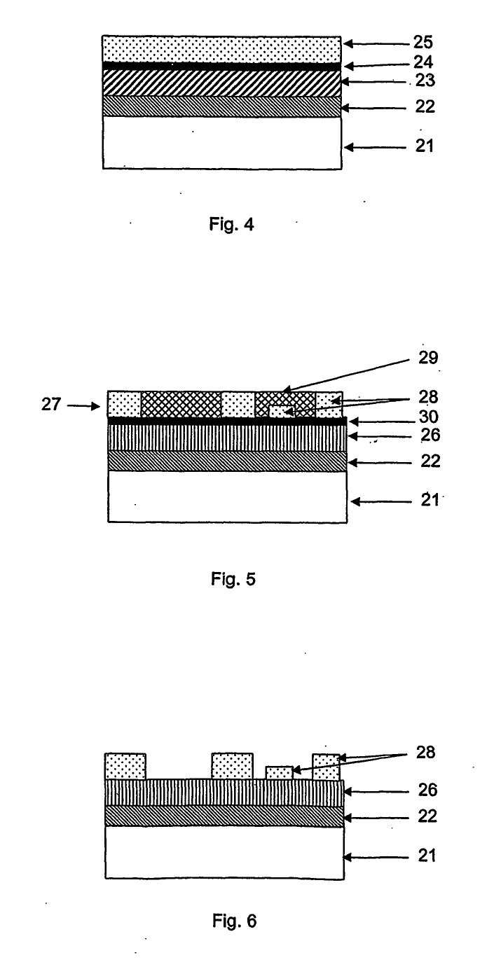

Over the hydroxide film 24 is deposited about 300 nm of amorphous silicon 25 (a-Si) by sputtering (or evaporation or PECVD) as illustrated in FIG. 4. Layers 23, 24 & 25 are the pre-cursors for the aluminium-induced crystallization (AIC) process. The sample is then annealed at temperatures at or below 650° and preferably at or below 500° C. for 2 hours in a nitrogen-purged atmospheric-pressure furnace to cause crystallisation of the amorphous silicon by the AIC process.

During the AIC process the aluminium and the silicon exchange the place and the a-Si is crystallised. Furthermore, on top of the 200 nm crystalline silicon 26 an overlayer 27 consisting of aluminium 29 and crystalline silicon inclusions 28 is formed, resulting in the arrangement seen in FIG. 5. In addition, there is a thin (˜30 nm) porous interfacial film 30 consisting of aluminium hydroxide and/or aluminium oxide between the polycrystalline silicon film 26 and the overlayer 27. The porous interfacial film 30 varies in thickness laterally and may contain a few pinpoint areas with direct contact between the polycrystalline silicon film 26 and the crystalline silicon inclusions 28. The crystalline silicon inclusions 28 are strongly connected to the underlying porous interfacial film 30 which is strongly connected to the underlying silicon film 26. Due to diffusion of Si through the interfacial film 30 during the AIC process, the interfacial film 30 may contain small amounts of Si contaminants.

The aluminium 29 and aluminium hydroxide and/or aluminium oxide film 30 of the overlayer 27 are etched off to achieve the state shown in FIG. 6. This etch preferably uses a phosphoric acid solution, comprising a 100% solution of 85% phosphoric acid at about 130° C. for about 20 minutes. Weaker solutions of phosphoric acid may also be used, with a corresponding increase in etching time. This etch removes the aluminium hydroxide layer and/or aluminium oxide 30 without significantly etching the underlying polycrystalline silicon layer 26, and by means of lateral underetching, the etch also removes the aluminium hydroxide and/or aluminium oxide layer 30 below the silicon islands 28, thereby significantly decreasing the adhesion of the semiconductor islands 28 in FIG. 6.

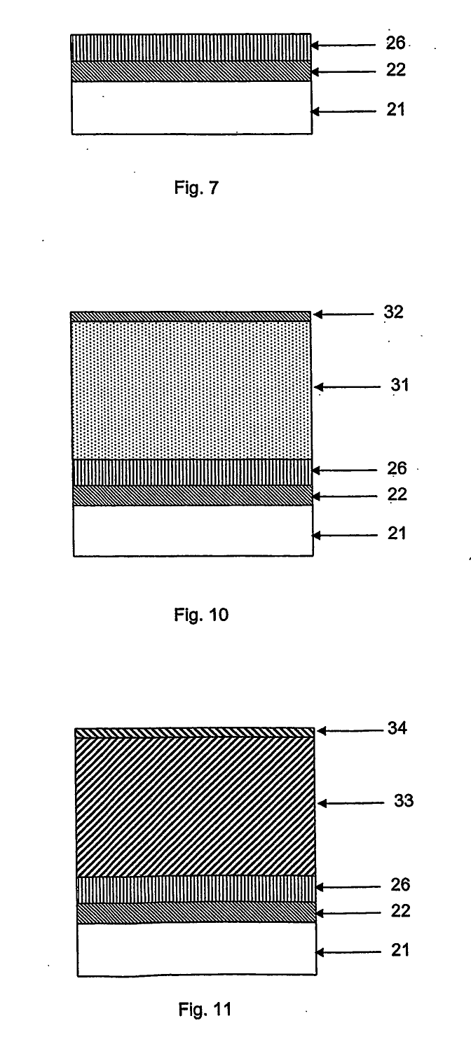

The significantly decreased adhesion strength, between the silicon islands 28 and the polycrystalline layer 26 makes possible a simple lift-off process to achieve removal of the silicon islands. A cleaning sequence is used to effect lift-off of the silicon islands 28, an example being ultrasonic treatment in deionized water in combination with a brush scrubbing process of the sample of FIG. 6, to thereby produce a polycrystalline silicon film with uniform thickness on the substrate. An additional, optional, processing step is a uniform surface treatment that improves the surface finish of the sample prior to subsequent device fabrication or use as a seed layer. FIG. 7 shows a schematic representation of a sample prepared to this stage in accordance with an embodiment of the present invention.

The sample seen in FIG. 7, which is a polycrystalline silicon film formed with the above AIC process on planar glass, shows a wafer-like smooth surface, and as seen in the FIB (focused ion beam) picture of FIG. 8 the grains of the polycrystalline silicon film are up to 20 μm wide, with an average width of about 10 μm. It is anticipated that grain sizes of up to 100 μm or more can be expected to be produced by this process. Experimentation has shown that a Si island free surface such as this is a key requirement for high material quality in the subsequent solid phase epitaxy step. The AIC polycrystalline silicon film shown in FIG. 7 is of exceptional material quality and highly p-type due to the Al content of about 2×10¹⁹ cm⁻³. If a doping polarity change is desired, the sample can be heated to 900° C., for up to 5 minutes, in the vicinity of an n-type spin-on doping source. An n-type AIC polycrystalline silicon film can then be formed with a low resistivity in the order of 0.002 106 cm. To prevent sticking of the glass, a graphite substrate holder is preferably used during the high-temperature anneal.

The UV reflectance of a silicon sample is a direct measure of its material quality. The reflectance of the sample seen in FIG. 7 was measured and compared with that of a high-quality commercial singlecrystalline silicon wafer. The results of that comparison can be seen in the graph of FIG. 9. The difference is less than 2% and clearly demonstrates the good material quality of the AIC film.

To fabricate a solar cell from the ˜200 nm crystalline Si layer (a so-called “seed layer”) produced by the process described above, the silicon must be thickened to a total of 0.5-3 μm to absorb most of the incident sunlight. In the subsequent solid phase epitaxy step the crystalline information of the seed layer is exploited and transferred into the subsequently formed crystalline layers.

To create a contamination and oxide free interface on the crystalline silicon seed layer 26, which is a crucial requirement for epitaxy, the seed layer is first immersed for 10 minutes in a fresh 1:1 mixture of hydrogen peroxide and sulfuric acid, followed by a rinse in de-ionized water, then immersed for 30 seconds in diluted (5%) hydrofluoric acid, then immersed in de-ionized water and then dried with gaseous nitrogen (using a “nitrogen gun”). The samples are then immediately transferred into the amorphous silicon deposition apparatus. The chemical procedure described above creates a hydrogen-terminated silicon surface (i.e., hydrogen atoms are bonded to the silicon surface atoms), which suppresses the re-growth of a silicon oxide film on the surface for quite some time (in order of 30 minutes at room temperature).

Using a high-vacuum electron-beam evaporation process, an amorphous n- or p-type (˜5×10¹⁶ cm⁻³ phosphorus or gallium) silicon layer 31 and an amorphous n⁺-type (˜2×10¹⁹ cm⁻³ phosphorus) silicon layer 32 are deposited at approximately 150° C. in one run (i.e., without interrupting the silicon deposition) to produce the structure seen in FIG. 10. The combined thickness of layers 31 and 32 is approximately 1 μm and is deposited at a rate of about 250 nm/min. Both the high rate and the high vacuum ensure semiconductor-grade material, which is essential for solar cells. The high rate allows the whole structure to be formed within less than 10 minutes. Other methods like PECVD need much longer for the same thickness.

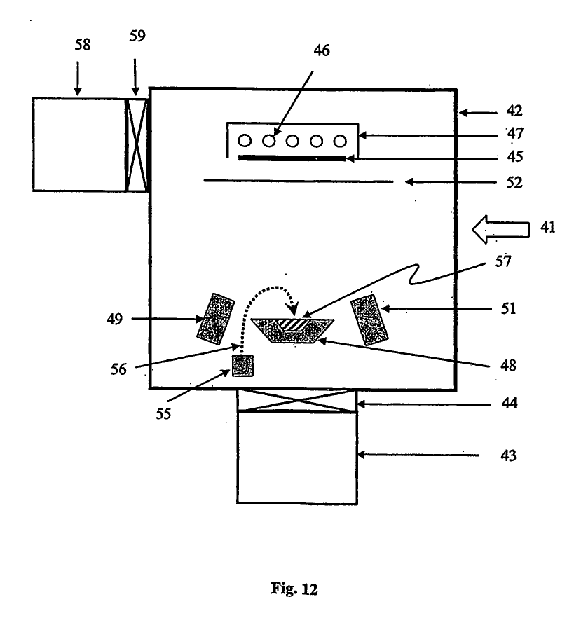

Referring to FIG. 12, the high-vacuum evaporation process is performed in an electron-beam evaporator for silicon evaporation 41 comprising a high-vacuum chamber 42 which is continuously evacuated using a high-vacuum pump 43. The high-vacuum pump 43 operates through a valve 44 which, to avoid damage to the high-vacuum pump 43, is only open if the chamber pressure is below the maximum operating pressure of the pump. The chamber is pumped down to this maximum pressure by a second, low-vacuum pump (not shown). In operation a base pressure of 5×10⁻⁷ Torr or lower is required to ensure low contamination levels in the deposited amorphous silicon. The sample 45 is transferred into the chamber via a loadlock 58 and then heated to the desired temperature by halogen lamps 46 enclosed in a molybdenum housing 47. A valve 59 between the loadlock 58 and the chamber 42 is used to separate the chamber 42 from the loadlock 58 while the loadlock is pumped down to a pressure of below the maximum operation pressure of the high-vacuum pump 43. The valve 59 is preferably opened at pressures in the loadlock 58 which are low enough to minimise the contamination of the chamber 42. As shown in FIG. 12 the sample 45 is heated from the back side (i.e. through the glass substrate) and the silicon side is oriented to face the melting pot 48 which holds solid silicon for thermal evaporation and subsequent deposition on the surface of the sample 45. The silicon within the melting pot is melted by an electron beam 56 created by an electron gun 55 and directed onto the silicon source material 57 using magnetic fields (not shown). There are additionally two resistively heated effusion cells 49, 51 for in-situ gallium and phosphorus doping during deposition. A shutter 52 is positioned between the sample and the e-beam evaporator to shield the sample until the silicon deposition process is ready to commence.

The structure of FIG. 10 is the pre-cursor for the following crystallisation step known as (homo-epitaxial) solid phase epitaxy (SPE). If a hetero-epitaxial SPE process is desired, the silicon within the melting pot is replaced by germanium for example and subsequently melted by the electron beam 56 created by the electron gun 55 as described above. If hetero-epitaxial SPE of a silicon-germanium alloy is desired, two separate melting pots can be used, one for silicon and one for germanium materials, and by the way of co-evaporation the amorphous silicon-germanium alloy to be crystallised by hetero-epitaxial SPE is deposited on the polycrystalline silicon seed layer.

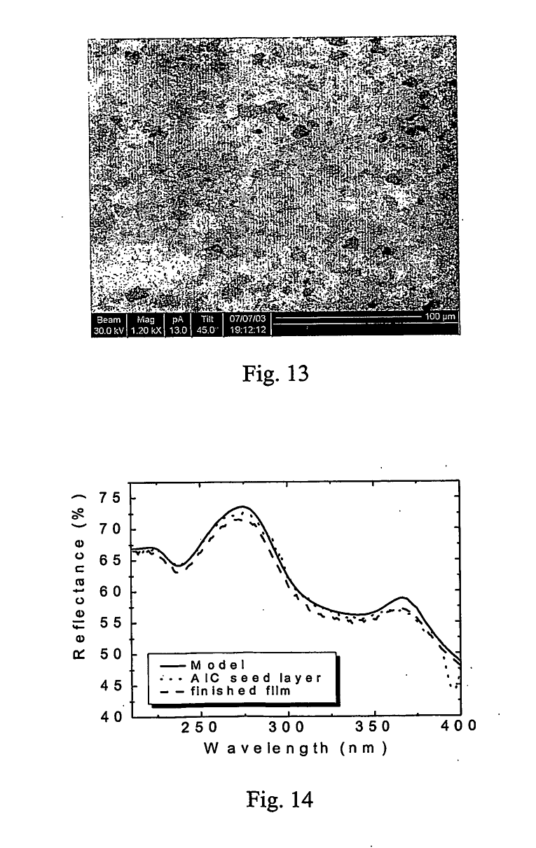

The SPE process is performed by a lamp-heated vacuum annealing process at about 540° C., whereby the halogen lamps 46 illuminate the silicon through the glass substrate 21. This process can be performed with a significantly reduced vacuum to that of the deposition step and a vacuum of 5×10⁻⁶ Torr is adequate. Alternatively, the SPE process may be performed in a nitrogen-purged atmospheric-pressure furnace. The doped amorphous silicon layers 31 and 32 of FIG. 10 fully crystallize within 17 hours, starting from the underlying AIC seed layer, to produce the structure of FIG. 11, in which the obtained doped crystalline silicon layers 33 and 34 have a similar crystalline structure and material quality as that of the seed layer 26. For certain device applications (for example solar cells) it is necessary to increase the fraction of electrically active dopant atoms by subjecting the sample to a short (<5 minutes) high-temperature anneal in the range 700-1000° C. To prevent sticking of the glass, a graphite substrate holder is preferably used during the high-temperature anneal. The thermal budget of such a rapid thermal process is small enough to make it compatible with commercially available glass substrates. The FIB picture seen in FIG. 13 shows similarly large grains as those seen in the thin crystalline seed layer (see FIG. 8). Also no surface roughness is visible in the FIB image.

Referring to FIG. 14, the UV reflectance measured on the sample of FIG. 13 (dashed curve in FIG. 14) shows very similar characteristics to that of the AIC seed layer 26 (dotted curve in FIG. 14). The small differences that are apparent are believed to be due to an oxide present on the surface of the finished silicon film, which was not removed prior to the reflectance measurement.

TABLE 1

| Sample | Peak (cm⁻¹) | FWHM (cm⁻¹) | Intensity |
|---|---|---|---|
| Silicon reference | 518.9 ± 0.2 | 6.3 ± 0.2 | 10700 ± 500 |
| AIC seed layer | 522.2 ± 0.6 | 6.8 ± 0.2 | 1800 ± 100 |
| Finished film | 519.2 ± 0.3 | 6.7 ± 0.4 | 6200 ± 1600 |

Since both FIB and UV reflectance exclusively probe the near-surface region of a sample, Raman measurements were performed on a silicon wafer reference, the AIC seed layer, and the finished device. Raman measurements probe the material quality of the bulk of the films (penetration depth of used Raman laser light ca. 1-2 μm). High intensity but mostly narrow peaks were observed, which are clear signs of good material quality. The full width at half maximum (FWHM) of the fabricated sample differs only marginally from the silicon wafer reference and is only slightly lower in intensity, which can be attributed to the lower thickness of the fabricated film. Results of the Raman measurements can be seen in Table 1.

The low thermal budget (which is compatible with commercial glass), the high deposition rate for the deposition of the main material (layers 31/33 and 32/34) and the simplicity of the process, which does not include the use of toxic gasses, make it a very attractive technique for industrial applications.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method of forming a polycrystalline semiconductor film on a supporting substrate of foreign material, the method comprising:
i. depositing a metal film onto a target surface of the substrate on which the polycrystalline semiconductor film is to be formed;
ii. forming a film of metal oxide and/or metal hydroxide on a surface of the metal;
iii. forming a layer of an amorphous semiconductor material over a surface of the metal oxide and/or metal hydroxide film;
iv. heating the substrate, the metal, the metal oxide and/or metal hydroxide film and the amorphous semiconductor material to a temperature at which the semiconductor layer is absorbed into the metal layer and deposited onto the target surface by metal-induced crystallisation (MIC) as a polycrystalline layer, whereby the metal is left as an overlayer covering the deposited polycrystalline layer, with semiconductor inclusions in the metal layer, and the polycrystalline semiconductor film and the overlayer separated by a porous interfacial metal oxide and/or metal hydroxide film, with which the semiconductor inclusions are in contact;
v. removing the metal in the overlayer and the interfacial metal oxide and/or metal hydroxide film with an etch which underetches the semiconductor inclusions to form freestanding islands weakly connected to the polycrystalline layer, without significantly thinning the underlying polycrystalline semiconductor layer;
vi. removing the freestanding semiconductor “islands” from the surface of the polycrystalline semiconductor layer by a lift-off process.

2. (canceled)

3. (canceled)

4. The method of claim 1 wherein the substrate comprises a sheet of substrate material over which a preliminary layer is deposited and the target surface is a surface of the preliminary layer.

5. (canceled)

6. The method of claim 1 wherein, as a result of the MIC step, metal atoms are left in the polycrystalline layer which act as dopants and after the lift-off process, the polycrystalline semiconductor layer is doped with a dopant which overcompensates the doping caused by the metal atoms left in the polycrystalline layer after the MIC step, thereby causing the polycrystalline semiconductor layer to have an overall doping polarity which is opposite to that which would occur due to the metal atoms alone.

7. (canceled)

8. (canceled)

9. The method of claim 1 wherein, as a result of the MIC step, metal atoms are left in the polycrystalline layer which act as dopants and the amorphous semiconductor material is doped during its formation with atoms that produce an opposite-polarity doping when compared to the polarity of doping caused by the metal atoms left in the polycrystalline layer after the MIC step, the opposite polarity doping being sufficient to overcompensate for the presence of the metal atoms whereby after the MIC step the net doping is opposite in polarity to that which would be produced by the metal atoms alone.

10. The method of claim 1, wherein the substrate is a material selected from the group comprising sapphire, quartz, glass (including float glass, borosilicate glass and other glass types), metal, graphite, ceramics, plastics and polymers.

11. The method of claim 1, wherein the polycrystalline semiconductor film is of a semiconductor material selected from the group comprising silicon, germanium, and an alloy of silicon and germanium.

12. The method of claim 1, wherein the metal is selected such that the metal forms a eutectic solution with the selected semiconductor.

13.-20. (canceled)

21. The method of claim 1, wherein the metal and metal oxide and/or metal hydroxide etch is performed with a phosphoric acid solution.

22. The method of claim 21 wherein the phosphoric acid solution is a 100% solution of 85% phosphoric acid, and the etch is performed at 130° C.±3° C. for 20 minutes±30 seconds.

23. The method of claim 1, wherein the lift-off process is selected from the group comprising an acoustic treatment in a solution bath, a brush scrubbing process, or a hydrodynamic jet process.

24. (canceled)

25. The method of claim 1, wherein the method further includes the step of, upon completion of the lift-off process, performing a uniform surface treatment to improve the surface finish of the sample prior to subsequent use of the semiconductor film.

26. (canceled)

27. The method of claim 1, wherein the metal layer has a thickness in the range of 30-500 nm.

28. The method of claim 1 wherein the amorphous semiconductor layer used in the metal-induced crystallisation process has a thickness in the range of 30-750 nm.

29. (canceled)

30. The method of claim 1, wherein the metal-induced crystallisation is performed by annealing the sample at a temperature of 650 ° C. or less.

31. (canceled)

32. The method of claim 1, wherein the polycrystalline layer formed by metal-induced crystallisation on a foreign substrate is used as a seed layer for the formation of a further polycrystalline layer, the method further comprising:
cleaning the surface of the seed layer to remove any oxides or other contaminants;
forming a second amorphous layer of a semiconductor material over the cleaned surface of the seed layer;
heating the substrate, the seed layer and the second amorphous layer to crystallise the semiconductor material by solid phase epitaxy (SPE).

33. The method of claim 32 wherein the semiconductor material of the seed layer and the second amorphous layer are of the same semiconductor material with the same or different doping.

34. The method of claim 32 wherein the semiconductor material of the seed layer and the second amorphous layer are different semiconductor materials.

35.-39. (canceled)

40. The method of claim 32, wherein the second amorphous layer is simultaneously doped as it is formed.

41.-49. (canceled)

50. The method of claim 32, wherein the amorphous semiconductor material of the second amorphous semiconductor layer is doped to a predetermined doping profile during an electron beam evaporation deposition process using resistively heated p-type and n-type dopant effusion cells in the vacuum electron-beam evaporation chamber while the deposition process takes place.

51.-53. (canceled)

54. The method of claim 32, wherein the step of cleaning the seed layer surface comprises a process which creates a hydrogen-terminated silicon surface and the substrate is transferred to the semiconductor deposition chamber within 60 minutes of completion of the cleaning step.

55.-90. (canceled)
